(19) United States
(12) Patent Application Publication
(10) Pub. No.: US 2026/0231503 A1
(43) Pub. Date: Aug. 6, 2026

(54) SEMICONDUCTOR STRUCTURE AND MANUFACTURING METHOD THEREOF

(71) Applicant: Winbond Electronics Corp., Taichung City (TW)

(72) Inventors: Yi-Chi Tsai, Tainan (TW); Feng-Jung Chang, Kaohsiung City (TW); Wei-Che Chang, Taichung City (TW); Yung-Wen Hung, Taichung City (TW)

(73) Assignee: Winbond Electronics Corp., Taichung City (TW)

(21) Appl. No.: 19/238,537

(22) Filed: Jun. 16, 2025

(30) Foreign Application Priority Data
Feb. 5, 2025 (TW) 114104064

(51) Int. Cl. H10D 64/23; H10D 64/01; H10D 64/27

(52) U.S. Cl. CPC H10D 64/2527; H10D 64/01; H10D 64/513

(57) ABSTRACT

A semiconductor structure and a manufacturing method thereof are provided. The semiconductor structure includes a substrate having an active area, a plurality of word line structures, a doped region, a plurality of pillar structures, a spacer and a contact. The plurality of word line structures are disposed in the substrate. The extending direction of the word line structure intersects with the extending direction of the active area. The doped region is disposed in the substrate in the active area and located between adjacent word line structures. The plurality of pillar structures are disposed on the substrate to surround the doped region. The spacer is disposed on the sidewalls of the pillar structures, so that the pillar structures and the spacer cover the ends of the active area together. The contact is disposed on the doped region and in contact with the spacer.

### CROSS-REFERENCE TO RELATED APPLICATION

This application claims the priority benefit of Taiwan application serial no. 114104064, filed on Feb. 5, 2025. The entirety of the above-mentioned patent application is hereby incorporated by reference herein and made a part of this specification.

### BACKGROUND

### Technical Field

The present invention relates to a semiconductor structure and a manufacturing method thereof.

### Description of Related Art

In the semiconductor process, a method for forming the contact that electrically connects the drain region to the bit line includes the following steps. A dielectric layer with an opening exposing the drain region is formed on the substrate. The opening is filled with a conductive material to form the contact. As the size of the device continues to shrink, the method described above has become difficult to apply to manufacture a smaller-sized device due to the limitations of the lithographic apparatus.

In another method, pillar structures are formed on the substrate to define the contact forming region, and the contact forming region is filled with a conductive material to form the contact. Since the pillar structure has a larger size, it is not restricted by the lithographic apparatus. However, the pillar structure with a large size leads to poor local critical dimension uniformity (LCDU).

### SUMMARY

The present invention provides a semiconductor structure and a manufacturing method thereof, wherein smaller pillar structures used to define the contact connected to the bit line are formed at the ends of the active areas, and a spacer is formed on the sidewalls of the pillar structures, so that the pillar structures and the spacer on the sidewalls of the pillar structures cover the entire ends of the active areas together.

The semiconductor structure of the present invention includes a substrate having an active area, a plurality of word line structures, a doped region, a plurality of pillar structures, a spacer and a contact. The plurality of word line structures are disposed in the substrate. The extending direction of the word line structure intersects with the extending direction of the active area. The doped region is disposed in the substrate in the active area and located between adjacent word line structures. The plurality of pillar structures are disposed on the substrate to surround the doped region. The spacer is disposed on the sidewalls of the pillar structures, so that the pillar structures and the spacer cover the ends of the active area together. The contact is disposed on the doped region and in contact with the spacer.

The manufacturing method of the semiconductor structure of the present invention includes the following steps. A substrate is provided, wherein the substrate has an active area, a plurality of word line structures are formed in the substrate, and an extension direction of the word line structures intersects with an extension direction of the active area. A doped region is formed in the substrate in the active area, wherein the doped region is located between adjacent word line structures. A plurality of pillar structures are formed on the substrate, wherein the plurality of pillar structures surround the doped region. A spacer is formed on the sidewalls of the pillar structures, so that the pillar structures and the spacer cover the ends of the active area together. A contact is formed on the doped region, wherein the contact is in contact with the spacer.

Based on the above, in the semiconductor structure of the present invention and the manufacturing method thereof, smaller pillar structures used to define the contact connected to the bit line are formed at the ends of the active areas, thereby avoiding poor LCDU of the pillar structures. In addition, the spacer is formed on the sidewalls of the pillar structures, so that the pillar structures and the spacer located on the sidewall of the pillar structures cover the entire ends of the active areas together, so that the ends of the active areas may be protected and not damaged in subsequent processes.

### BRIEF DESCRIPTION OF THE DRAWINGS

FIGS. 1A to 1F are cross-sectional views of the manufacturing method of the semiconductor structure according to the first embodiment of the present invention.

FIG. 2 is a schematic top view of the substrate in the embodiment of the present invention.

FIG. 3 is a schematic top view of the initial pillar structures formed on the substrate in th embodiment of the present invention.

FIG. 4 is a schematic top view of the spacer formed on the sidewalls of the initial pillar structures in the embodiment of the present invention.

FIG. 5 is a schematic cross-sectional view of the semiconductor structure according to the second embodiment of the present invention.

### DESCRIPTION OF THE EMBODIMENTS

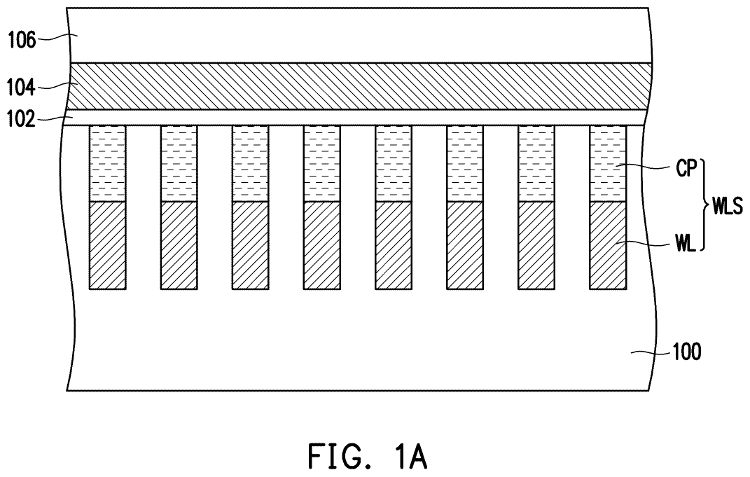

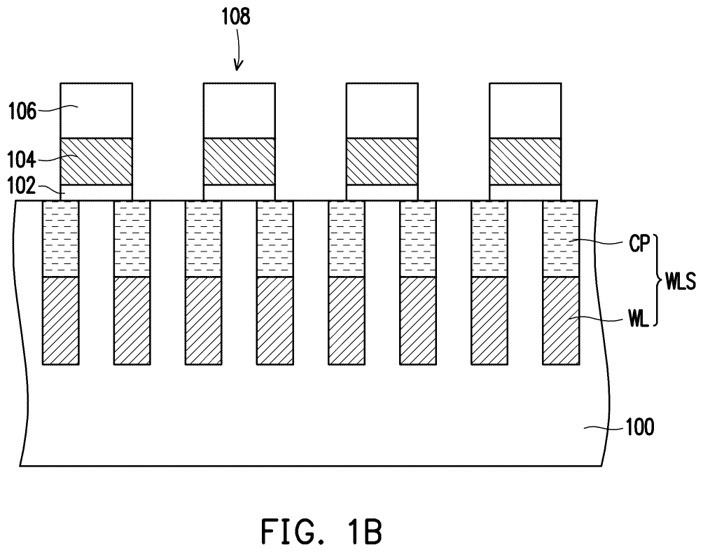

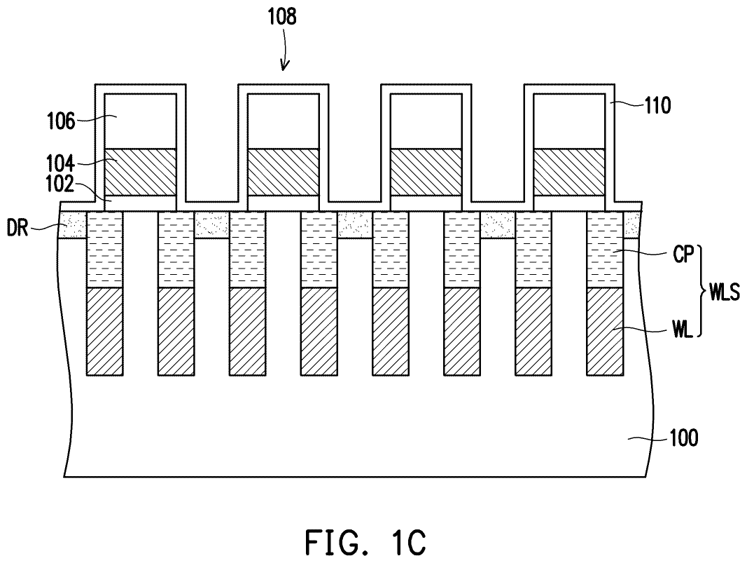

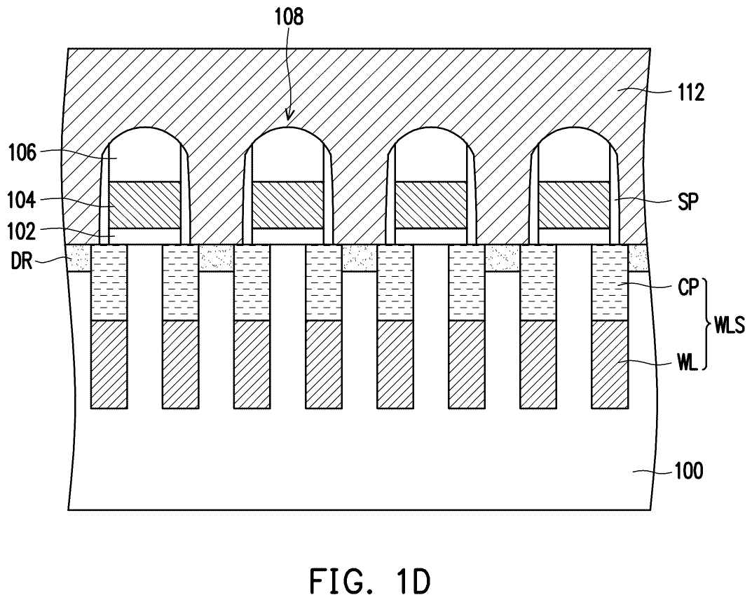

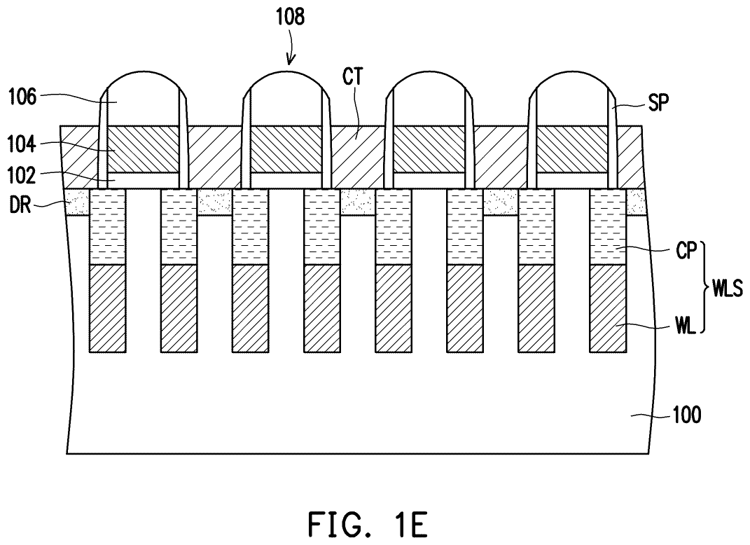

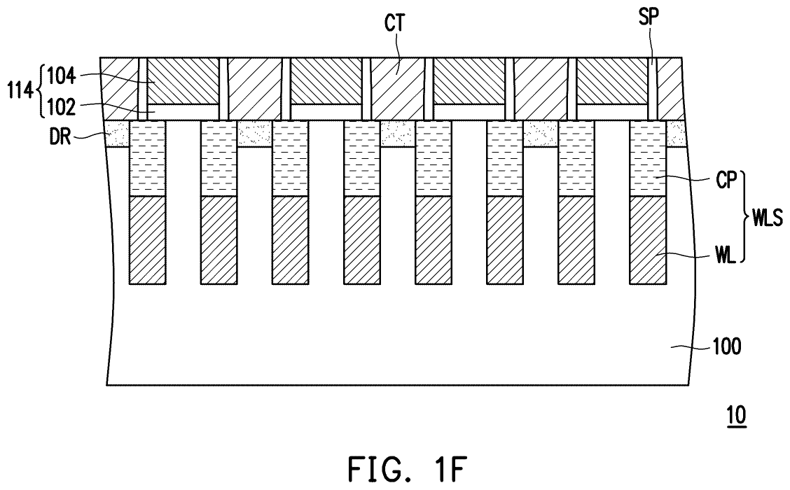

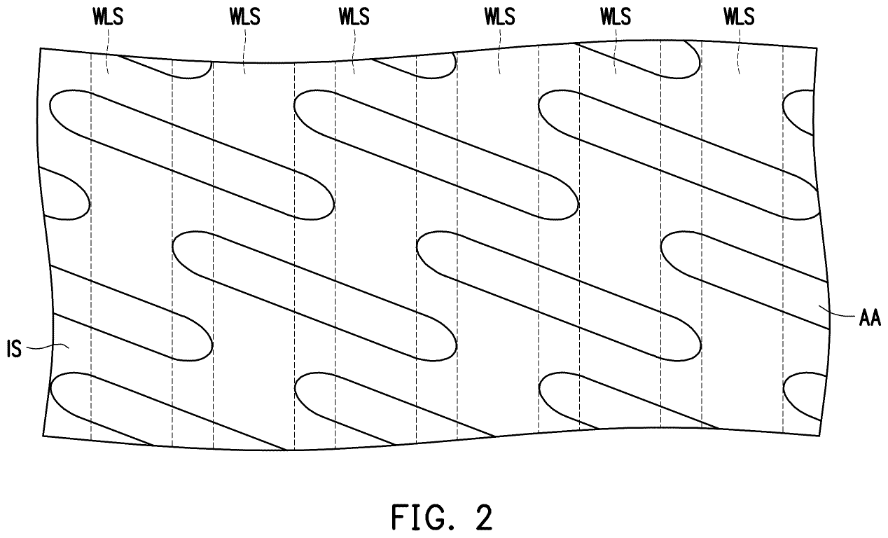

Referring to FIG. 1A, a substrate 100 is provided. The substrate 100 is, for example, a silicon substrate. As shown in FIG. 2, the substrate 100 may have a plurality of active areas AA defined by an isolation structure IS formed therein, a plurality of word line structures WLS are formed in the substrate 100 and arranged parallel to each other, and the extension direction of the word line structure WLS intersects with the extension direction of the active area AA. The isolation structure IS is, for example, a shallow trench isolation structure. The word line structure WLS includes a word line WL and a capping layer CP formed on the top surface of the word line WL, but the present invention is not limited thereto. The capping layer CP is, for example, a silicon nitride layer. The methods for forming the isolation structure IS and the word line structures WLS are well known to those skilled in the art and will not be described in detail herein.

Then, a silicon oxide layer 102, a doped polysilicon layer 104 and a mask layer 106 are sequentially formed on the substrate 100. The material of the mask layer 106 is, for example, silicon oxide. The manufacturing method of the present embodiment may be integrated with the process in the peripheral region (not shown) of the substrate 100. In this case, in the peripheral region, the silicon oxide layer 102 may be used to form the gate dielectric layer of the transistor, and the doped polysilicon layer 104 may be used to form the gate of the transistor.

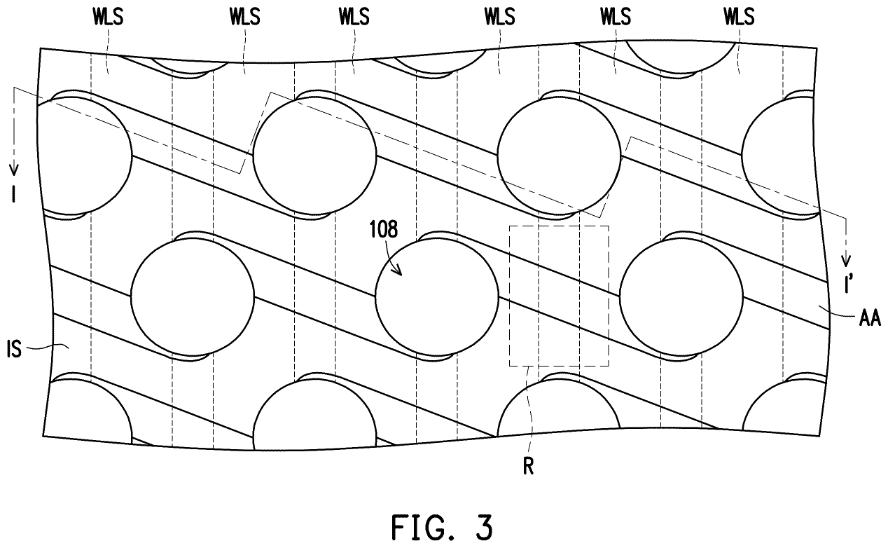

Referring to FIG. 1B, a patterning process is performed on the mask layer 106, the doped polysilicon layer 104 and the silicon oxide layer 102 to form a plurality of initial pillar structures 108 on the substrate 100. The initial pillar structure 108 is formed by the stacked silicon oxide layer 102, doped polysilicon layer 104 and mask layer 106. The initial pillar structures 108 are used to define the regions forming contacts connected to bit lines. As shown in FIG. 3, in the extension direction of the active area AA, two initial pillar structures 108 are respectively located at two opposite ends of the active area AA and do not completely cover the ends of the active area AA. In addition, four initial pillar structures 108 adjacent to each other surround a region R forming a contact connected to the bit line. The cross section shown in FIG. 1B may refer to the cross section line I-I′ in FIG. 3.

On the other hand, the initial pillar structure 108 formed at the end of the active area AA does not need to completely cover the end of the active area AA, that is, a part of the end of the active area AA may be exposed. In this way, there is no need to form a pillar structure with a larger size in order to make the initial pillar structure 108 completely cover the end of the active area AA, thereby avoiding the poor LCDU of the initial pillar structures 108.

Referring to FIG. 1C, doped regions DR are formed in the substrate 100 in the active areas AA in the regions R. The doped regions DR may be formed by using the initial pillar structures 108 as a mask to perform an ion implantation process to implant the dopant into the substrate 100. As such, the doped region DR is located between adjacent word line structures WLS and surrounded by the initial pillar structures 108 formed on the substrate 100. The doped regions DR may be used as the drain regions electrically connected to the subsequently formed bit lines.

After forming the doped regions DR, a spacer material layer 110 is conformally formed on the substrate 100. The material of the spacer material layer 110 is, for example, silicon oxide or silicon nitride. The spacer material layer 110 covers the top surfaces and the sidewalls of the initial pillar structures 108 and the top surface of the substrate 100. The thickness of the spacer material layer 110 located on the sidewalls of the initial pillar structures 108 must be such that the spacer material layer 110 may cover the exposed ends of the active areas AA.

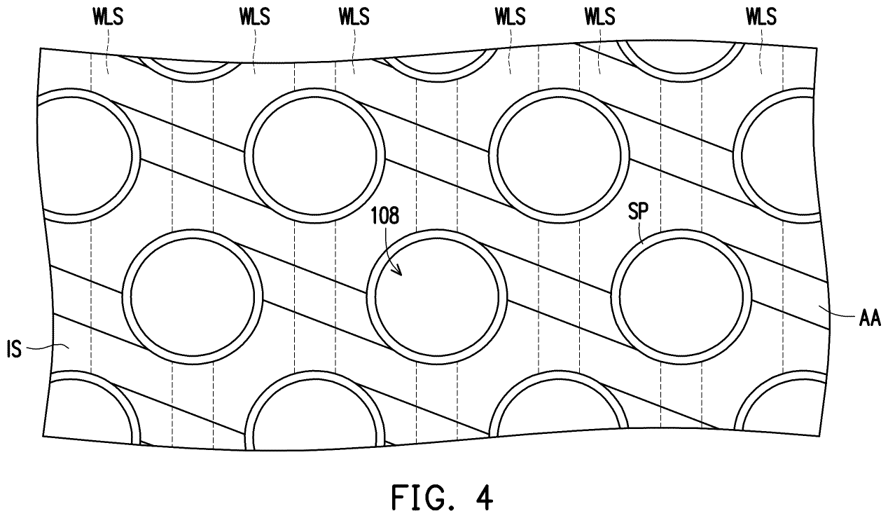

Referring to FIG. 1D, an etching process is performed to remove a part of the spacer material layer 110 until the top surface of the mask layer 106 and the substrate 100 are exposed. In this way, a spacer SP is formed on the sidewalls of the initial pillar structures 108, and the spacer SP covers the ends of the active areas AA. The initial pillar structure 108 and the spacer SP formed on the sidewall of the initial pillar structure 108 together cover the entire end of the active area AA, as shown in FIG. 4. In subsequent processes, the ends of the active areas AA may be protected from damage.

During the etching process, in addition to removing a part of the spacer material layer 110, a part of the mask layer 106 may also be removed simultaneously, so that the mask layer 106 has a curved top surface. Since the mask layer 106 has a curved top surface, in the subsequent process for forming a contact connected to the doped region DR, a contact material layer may completely fill the space between the initial pillar structures 108 to void the formation of overhangs.

After forming the spacer SP, a contact material layer 112 is formed on the substrate 100. The contact material layer 112 covers the initial pillar structures 108 and the spacer SP, and completely fills the space between the initial pillar structures 108. The material of the contact material layer 112 is, for example, doped polysilicon.

Referring to FIG. 1E, a part of the contact material layer 112 is removed until the top surface of the mask layer 106 is exposed. Contacts CT connected to the doped regions DR are formed, and the contacts CT are in contact with the spacer SP. The method for removing the part of the contact material layer 112 is, for example, performing an etching-back process. The top surface of the formed contact CT and the top surface of the doped polysilicon layer 104 in the initial pillar structure 108 are coplanar, but the present invention is not limited thereto. When the top surface of the contact CT and the top surface of the doped polysilicon layer 104 are coplanar, it is beneficial to the flatness of the layer subsequently formed thereon.

Referring to FIG. 1F, the mask layer 106 is removed. When removing the mask layer 106, a part of the spacer SP may be removed simultaneously, so that the top surface of the contact CT, the top surface of the doped polysilicon layer 104 and the top surface of the spacer SP are coplanar, which is beneficial to the flatness of the layers subsequently formed thereon. After removing the mask layer 106, the remained doped polysilicon layer 104 and the remained silicon oxide layer 102 in the initial pillar structure 108 form a pillar structure 114 of the present embodiment. In this way, a semiconductor structure 10 of the present embodiment is formed.

In the semiconductor structure 10, the position of the contact CT used to electrically connect to the drain region and the bit line is defined by the pillar structures 114, and the spacer SP is disposed on the sidewalls of the pillar structures 114. Therefore, even if smaller pillar structures 114 are formed to avoid the poor LCDU of the pillar structures 114, the ends of the active areas AA may be protected from being damaged in subsequent processes because the pillar structures 114 and the spacer SP located on the sidewalls of the pillar structures 114 may cover the entire ends of the active areas AA together.

In addition, in the semiconductor structure 10, the spacer SP is disposed between the pillar structure 114 and the contact CT. When the material of the pillar structure 114 and the material of the contact CT are both doped polysilicon, in the subsequent manufacturing process, the spacer SP may effectively prevent the dopant in the pillar structure 114 from diffusing into the contact CT and prevent the dopant in the contact CT from diffusing into the pillar structure 114, thereby preventing the resistance of the contact CT from changing and affecting the electrical properties of the device.

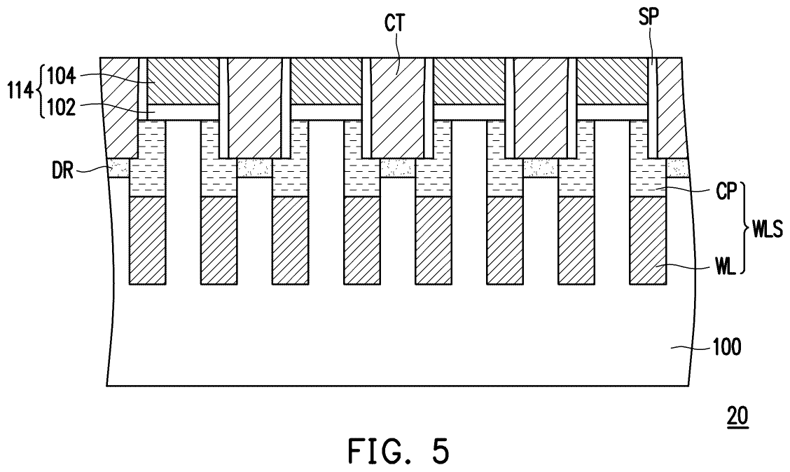

FIG. 5 is a schematic cross-sectional view of the semiconductor structure according to the second embodiment of the present invention. The same devices as those in the first embodiment will be denoted by the same reference symbols.

Referring to FIG. 5, in the semiconductor structure 20 of the present embodiment, the top surface of the substrate 100 below the pillar structures 114 is higher than the top surface of the remaining portion of the substrate 100.

During the patterning process of FIG. 1B, in addition to removing a part of the mask layer 106, a part of the doped polysilicon layer 104 and a part of the silicon oxide layer 102, a part of the substrate 100 and a part of the capping layer CP in the word line structure WLS are further removed, so that the top surface of the substrate 100 below the initial pillar structures 108 is higher than the top surface of the remaining portion of the substrate 100. In this way, the contact CT formed in the step of FIG. 1E may have a greater thickness, and the bottom surface of the contact CT (the top surface of the doped region DR used as the drain region) may be lower than the top surface of the substrate 100 below the pillar structures 114.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure comprising:
a substrate, having an active area;
a plurality of word line structures, disposed in the substrate, wherein an extension direction of the word line structures intersects with an extension direction of the active area;
a doped region, disposed in the substrate in the active area and located between adjacent word line structures;
a plurality of pillar structures, disposed on the substrate to surround the doped region;
a spacer, disposed on sidewalls of the pillar structures such that the pillar structures and the spacer cover ends of the active area together; and
a contact, disposed on the doped region and in contact with the spacer.

2. The semiconductor structure of claim 1, wherein two pillar structures of the plurality of pillar structures are respectively located at two opposite ends of the active area in the extending direction of the active area.

3. The semiconductor structure of claim 2, wherein the two pillar structures do not completely cover the opposite ends of the active area.

4. The semiconductor structure of claim 1, wherein a top surface of the contact, top surfaces of the pillar structures and a top surface of the spacer are coplanar.

5. The semiconductor structure of claim 1, wherein a material of the contact comprises doped polysilicon.

6. The semiconductor structure of claim 1, wherein the pillar structure comprises:
a silicon oxide layer, disposed on the substrate; and
a doped polysilicon layer, disposed on the silicon oxide layer.

7. The semiconductor structure of claim 1, wherein a material of the spacer comprises silicon oxide or silicon nitride.

8. The semiconductor structure of claim 1, wherein a top surface of the substrate below the pillar structures is higher than a top surface of a remaining portion of the substrate.

9. The semiconductor structure of claim 1, wherein the word line structure comprises a word line and a capping layer disposed on a top surface of the word line.

10. A manufacturing method of a semiconductor structure, comprising:
providing a substrate, wherein the substrate has an active area, a plurality of word line structures are formed in the substrate, and an extension direction of the word line structures intersects with an extension direction of the active area;
forming a doped region in the substrate in the active area, wherein the doped region is located between adjacent word line structures;
forming a plurality of pillar structures on the substrate, wherein the plurality of pillar structures surround the doped region;
forming a spacer on the sidewalls of the pillar structures, so that the pillar structures and the spacer cover the ends of the active area together; and
forming a contact on the doped region, wherein the contact is in contact with the spacer.

11. The manufacturing method of claim 10, wherein a forming method of the pillar structures, the spacer and the contact comprises:
forming a silicon oxide layer on the substrate;
forming a doped polysilicon layer on the silicon oxide layer;
forming a mask layer on the doped polysilicon layer;
performing a patterning process on the mask layer, the doped polysilicon layer and the silicon oxide layer to form a plurality of initial pillar structures, wherein the initial pillar structure is formed by stacking the silicon oxide layer, the doped polysilicon layer and the mask layer, two initial pillar structures of the plurality of initial pillar structures are respectively located at two opposite ends of the active area in an extension direction of the active area, and the initial pillar structures located at the ends do not completely cover the ends of the active area;
conformally forming a spacer material layer on the substrate;
performing an etching-back process to remove a part of the spacer material layer until a top surface of the mask layer and the substrate are exposed;
forming a contact material layer on the substrate, wherein the contact material layer covers the plurality of initial pillar structures;
removing a part of the contact material layer until the top surface of the mask layer is exposed; and
removing the mask layer to form the pillar structures.

12. The manufacturing method of claim 11, wherein the doped region is formed after the patterning process and before forming the spacer material layer.

13. The manufacturing method of claim 11, wherein a top surface of the substrate below the pillar structures is higher than a top surface of a remaining portion of the substrate.

14. The manufacturing method of claim 11, wherein a material of the mask layer comprises silicon oxide.

15. The manufacturing method of claim 11, wherein the mask layer has a curved top surface after the etching-back process.

16. The manufacturing method of claim 11, wherein a method for removing a part of the contact material layer comprises performing an etching-back process.

17. The manufacturing method of claim 11, wherein a top surface of the contact material layer and a top surface of the doped polysilicon layer in the initial pillar structure are coplanar after removing the part of the contact material layer.

18. The manufacturing method of claim 11, wherein, a part of the spacer material layer is removed when the mask layer is removed, so that a top surface of the contact material layer, a top surface of the doped polysilicon layer and a top surface of the spacer material layer are coplanar.

19. The manufacturing method of claim 11, wherein a material of the contact material layer comprises doped polysilicon.

20. The manufacturing method of claim 11, wherein a material of the spacer material layer comprises silicon oxide or silicon nitride.
